(19) United States
(12) Patent Application Publication
(10) Pub. No.: US 2009/0136712 A1
(43) Pub. Date: May 28, 2009

(54) FILM-LIKE ADHESIVE AND METHOD FOR CARRYING THE SAME

(75) Inventor: Shiro SATO, Sakata-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/273,219

(22) Filed: Nov. 18, 2008

(30) Foreign Application Priority Data
Nov. 28, 2007 (JP) 2007-306945

(51) Int. Cl. B32B 3/10; H01L 21/677

(52) U.S. Cl. 428/138; 414/800

(57) ABSTRACT

A film-like adhesive includes: a film including a separator and an adhesive layer provided on a first surface of the separator, the film including a hole going through at least one of the adhesive layer and the separator, the hole extending along a first direction, the first direction extending from the first surface of the separator to a second surface of the separator being opposite to the first surface of the separator.

The entire disclosure of Japanese Patent Application No. 2007-306945, filed Nov. 11, 2008 is expressly incorporated by reference herein.

### BACKGROUND

1. Technical Field

The present invention relates to a film-like adhesive and a method for carrying the same.

2. Related Art

FIGS. 8A and 8B are drawings showing an example of a structure of an anisotropic conductive film (ACF) reel 50 according to an example of a related art. FIG. 9 is a schematic diagram illustrating a method for carrying the ACF reel 50. As shown in FIGS. 8A and 8B, the ACF reel 50 is composed with an ACF 51 and a film-like separator 53 that overlaps with one of the surfaces of the ACF 51. As shown in FIG. 9, an ACF carrying device 60 includes, for instance, a pair of grip rollers 61 and 62, and a motor 63 that causes the grip roller 61 to rotate on its axis. A method for carrying the ACF reel 50 includes, for instance, interposing the ACF reel 50 between the pair of grip rollers 61 and 62, and rotating the grip roller 61 in this state, so as to feed the ACF reel 50 in its longitudinal direction. Such a method is disclosed, for instance, in JP-A-10-313024. Moreover, another un-illustrated known method for feeding the ACF reel 50 in the longitudinal direction includes immobilizing the separator 53 in an adsorptive manner with a suction apparatus and moving the suction apparatus in this state.

As described, in the methods for carrying the ACF reel 50, states of the ACF reel 50 include being interposed between grip rollers or being immobilized in an adsorptive manner. However, each one of those methods includes a problem of fluctuation in a feed amount (length of carriage per feed) relative to a packaging substrate, caused by the slipping of the ACF reel 50 during its carriage. Insufficient feed amount of the ACF reel 50 causes an adhesion failure between the packaging substrate (hereafter referred to as PKG substrate) and an integrated circuit (IC) chip, resulting in a yield decrease of semiconductor devices.

In order to avoid such problems, it has been necessary in the known techniques to set the feed amount of the ACF reel 50 to be sufficiently longer than the target value, as well as to ensure the wider ACF bonding area within the PKG substrate. Large ACF bonding areas inhibit size reduction of the packages and modules.

### SUMMARY

An advantage of the invention is to provide a film-like adhesive that improves its feeding precision and a method for carrying the same.

According to a first aspect of the invention, a film-like adhesive includes: a film including a separator and an adhesive layer provided on a first surface of the separator, the film including a hole going through at least one of the adhesive layer and the separator, the hole extending along a first direction, the first direction extending from the first surface of the separator to a second surface of the separator being opposite to the first surface of the separator. Here, examples of the adhesive layer according to this aspect include an anisotropic conductive (ACF) and a non conductive film (NCF).

In this film-like adhesive, the separator includes a protruding area protruding from the adhesive layer in plan view, and the hole is provided only in the protruding area.

In this case, the protruding area is provided at each of both sides of the adhesive layer, along a longitudinal direction of the film, and the hole is provided in the protruding area at each of the both sides.

In this adhesive, the film includes a plurality of the holes, the plurality of the holes, being equally spaced along a longitudinal direction of the film.

In this film-like adhesive, the separator includes a first section and a second section different from the first section, and the adhesive layer is provided only on the first section of the separator. Moreover, the hole is provided only in the second section of the separator.

In this case, the film includes a plurality of the holes including a first hole and a second hole, the second section of the separator includes a third section and a fourth section different from the third section, and the first section is positioned between the third section and the fourth section. Further, the first hole is provided in the third section and the second hole is provided in the fourth section.

According to the above aspect of the invention, the film-like adhesive is carried in the longitudinal direction, by moving the pins that are inserted and fit into the guiding holes. Moreover, the pins are inserted into the guiding holes at the time of carrying the film-like adhesives, thereby preventing the misalignment and the slipping of the film-like adhesive. This improves the carrying (feeding) precision of the film-like adhesive, thereby contributing to a size reduction of the packages and modules. Moreover, the film-like adhesive according to the above aspect of the invention allows for: using the adhesive layer without wastage since the guiding holes are not provided in the adhesive layer; and preventing the pins from contacting the adhesive layer.

According another aspect of the invention, a method for carrying a film-like adhesive includes inserting a pin into a hole of the film-like adhesive, and carrying the pin in a longitudinal direction of a film. In this method, the film includes a separator and an adhesive layer provided on a first surface of the separator. Moreover, the film includes a hole going through at least one of the adhesive layer and the separator, the hole extending along a first direction, the first direction extending from the first surface of the separator to a second surface of the separator being opposite to the first surface of the separator.

This method for carrying the film-like adhesive according to the second aspect of the invention allows for carrying the film-like adhesive in the longitudinal direction. Moreover, the pins are inserted and fit into the guiding holes at the time of carrying the film-like adhesives, thereby preventing the misalignment and the slipping of the film-like adhesive. This improves the carrying (feeding) precision of the film-like adhesives, thereby contributing to a size reduction of the packages and modules.

### BRIEF DESCRIPTION OF THE DRAWINGS

The invention will be described with reference to the accompanying drawings, wherein like numbers reference like elements.

FIGS. 1A through 1D are drawings illustrating an example of a structure of an ACF reel according to an embodiment.

FIGS. 2A and 2B are drawings illustrating examples of a desirable combination of a perforation hole and a pin.

FIG. 3 is a drawing illustrating an example of a method for carrying the ACF reel.

FIGS. 4A through 4D are drawings illustrating an example of a structure of an ACF reel according to another embodiment.

FIGS. 5A and 5B are drawings illustrating an example of a method for carrying the ACF reel.

FIGS. 6A and 6B are drawings comparing an aspect of the present invention to a known technique.

FIGS. 7A and 7B are drawings illustrating an example of gears.

FIGS. 8A and 8B are drawings illustrating an example of a structure of an ACF reel according to the known technique.

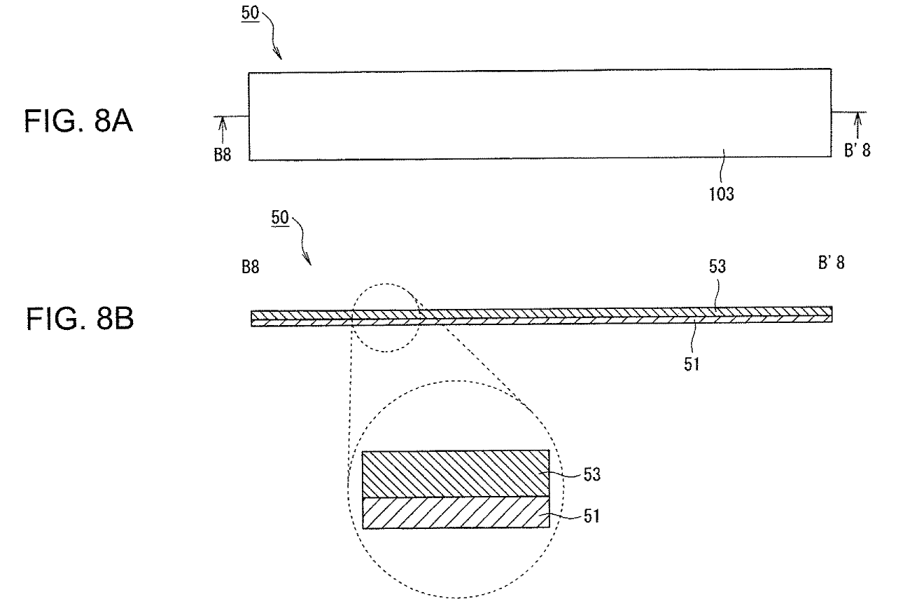

FIG. 9 is a drawing illustrating an example of a method for carrying the ACF reel according to the known technique.

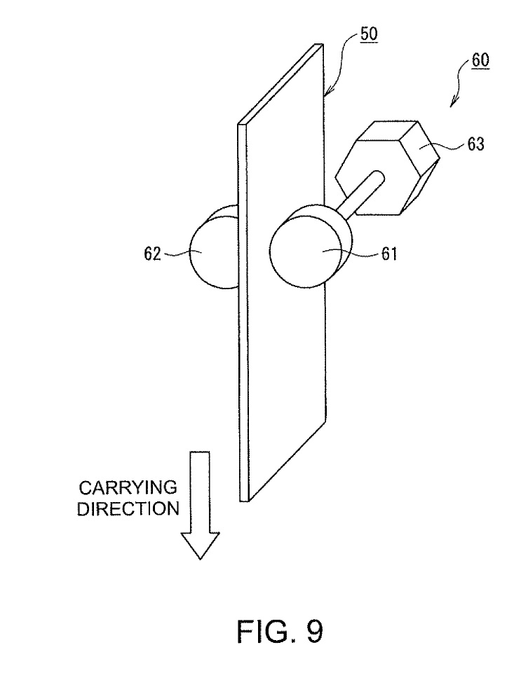

### DESCRIPTION OF EXEMPLARY EMBODIMENTS

The embodiments of the invention will now be described with reference to the accompanying drawings.

### (1) First Embodiment

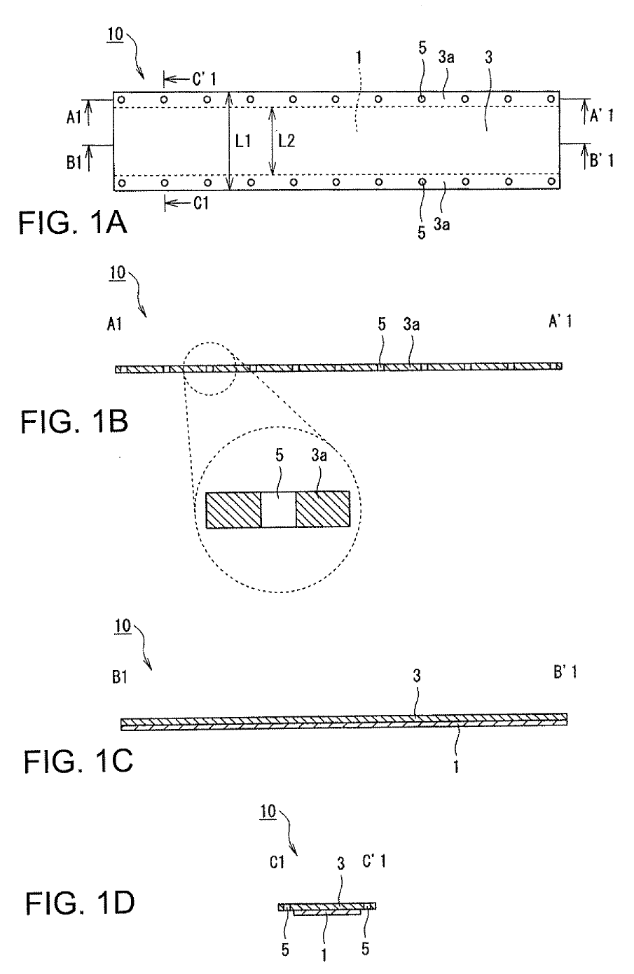

FIGS. 1A through 1D are drawings illustrating an example of a structure of an ACF reel 10 according to a first embodiment of the invention, where FIG. 1A is a plan view, FIG. 1B is a sectional view of FIG. 1A cut along A1-A′1, FIG. 1C is a sectional view of FIG. 1A cut along B1-B′1, FIG. 1D is a sectional view of FIG. 1A cut along C1-C′1.

As shown in FIGS. 1A through 1D, the ACF reel 10 is composed with an ACF 1 and a film-shaped separator 3 that overlaps with the ACF 1. The ACF 1 is an adhesive layer, and is formed with resin, such as thermosetting epoxy resin, in which conductive particles are diffused. The separator 3 is formed with, for instance, polyethylene terephthalate (PET). The separator 3 is formed to be wider than the ACF 1, and part of the separator 3 protrudes from both sides of the ACF 1 in its longitudinal direction. Hereafter, protruding regions of the separator 3 protruding from the ACF 1 in plan view will be referred to as protruding regions 3a.

Further, as shown in FIGS. 1A through 1D, each of the protruding regions 3a include a plurality of perforation holes 5 for feeding an ACF reel 10 in its longitudinal direction. These perforation holes 5 are through holes penetrating the separator 3 in the thickness direction, arranged to be evenly spaced along the longitudinal direction of the ACF reel 10. Here, the thickness direction means a direction extending from a first surface to a second surface in a sectional view. The first surface means one of the top and the bottom surfaces, and the second surface means the other one of the top and the bottom surfaces. The thickness direction may also be referred to as a direction that penetrates a multiplayer including the ACF 1 and the separator.

The perforation holes 5 are formed only in the protruding regions 3a, and not in a multilayered area in which the ACF 1 overlaps the separator 3. Referring now to FIG. 1A, the ranges of L1 and L2 are respectively for instance, from 1 to 20 mm and from 2 to 13 mm, where L1 is the width of the entire ACF reel 10 including the protruding regions, and L2 is the width of the ACF 1.

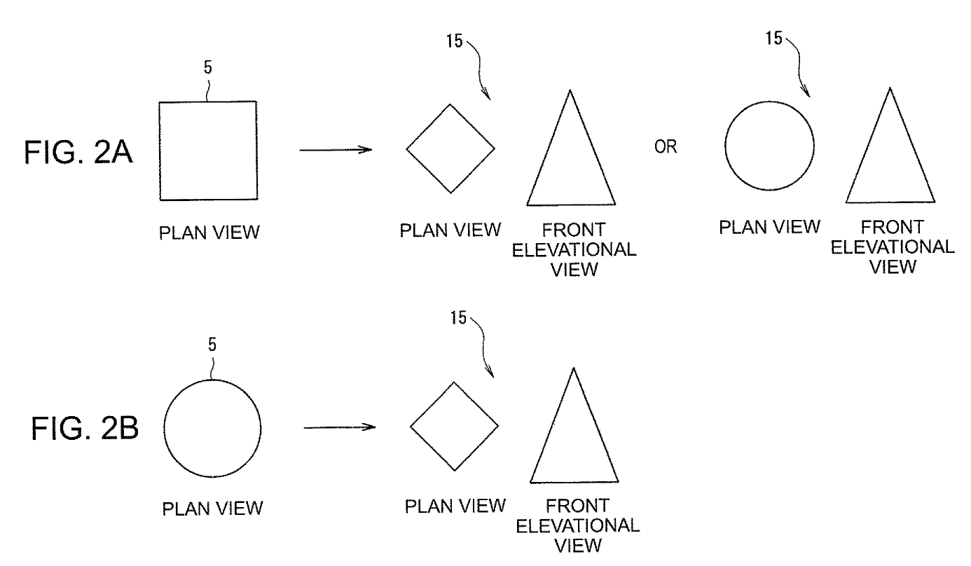

FIGS. 2A and 2B are drawings illustrating examples of a desirable combination of one of the perforation holes 5 and the corresponding pins 15. As shown in FIG. 2A, if the planer shape of the perforation holes 5 is square, the corresponding shapes of the pins 15 include pyramid and circular cone. Moreover, as shown in FIG. 2B, if the planer shape of the perforation holes 5 is a circle, the corresponding shape of the pins 15 is pyramid. With such combinations, an internal surface of each of the perforation holes 5 makes a point contact with an external surface of each of the pins 15, at the time of inserting the pins 15 into the perforation holes 5. This facilitates an easy insertion of the pins 15, as well as backlash reduction (i.e. movable margin) between the perforation holes 5 and the pins 15, thereby contributing to the improvement of the carrying (feeding) precision.

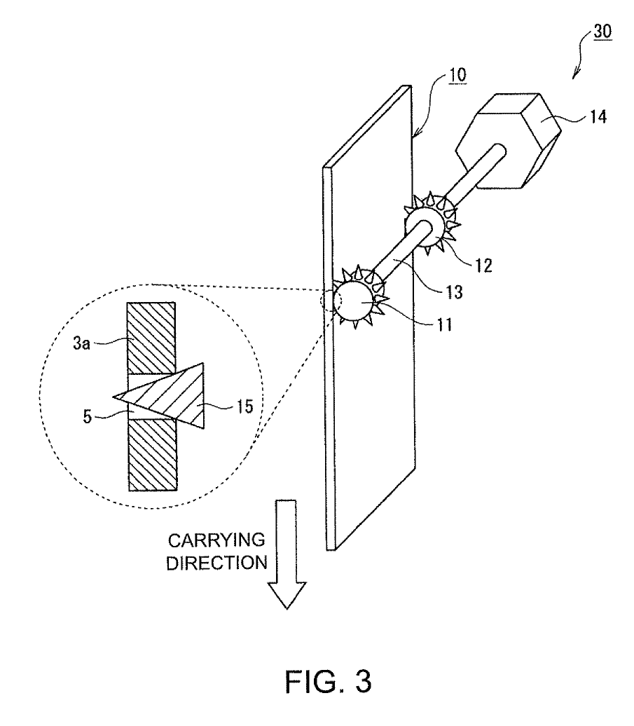

FIG. 3 is a schematic diagram illustrating an example of a method for carrying the ACF reel 10. As shown in FIG. 3, an ACF carrying device 30 includes, for instance, a pair of gears 11 and 12, a common axis 13 thereof, and a motor 14 that causes the gears 11 and 12 to rotate on the axis 13. A plurality of pins 15 are provided on the external surface of the gears 11 and 12, and the pins 15 are adjusted so that the spacing of the pins 15 match the spacing of the perforation holes 5. In this ACF carrying device 30, the shape of the pins 15 is selected in accordance with the shape of the perforation holes 5, so that the external surface of each of the pins 15 makes a point contact with the internal surface of each of the perforation holes 5, at the time of inserting the pins 15 into the perforation holes 5. For instance, refer to FIGS. 2A and 2B.

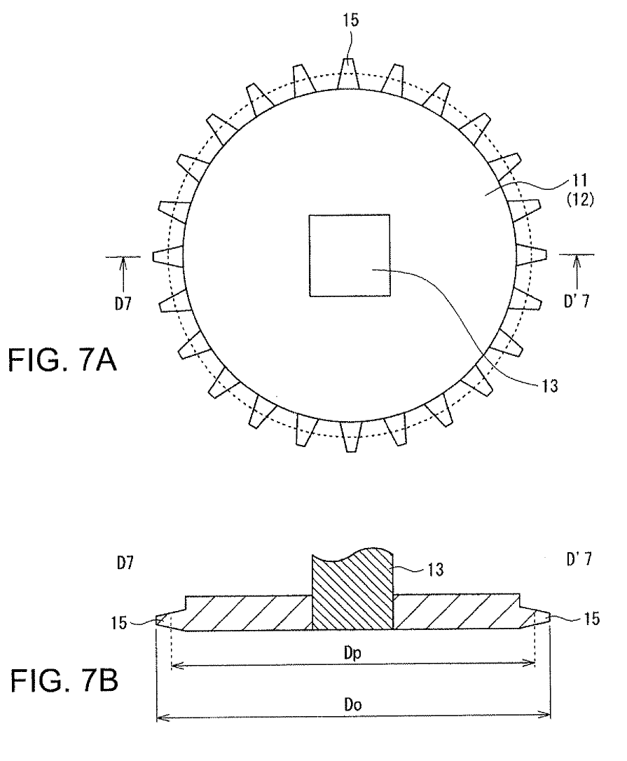

A pitch diameter Dp is represented in formula 1, where T is the number of pins (i.e. the number of teeth of the gear) and P is the pitch of the perforation holes 5. As shown in FIGS. 7A and 7B, the pitch diameter Dp is a diameter of a circle formed by connecting the center points of the pins 15. An external diameter Do of the sprocket holes is represented in formula 2. As shown in FIGS. 7A and 7B, the external diameter Do is a diameter of a circle formed by connecting the apexes of the pins 15.

Dp=P/(sin(180/T)) Formula 1

Do=P(0.6+cot(180/T)) Formula 2

In case of carrying the ACF reel 10 over the PKG substrate (the wiring substrate) using the ACF carrying device 30 shown in FIG. 3, the pins 15 provided on the external surfaces of the gears 11 and 12 are inserted into the perforation holes 5 of the ACF reel 10, and the gears 11 and 12 are rotated in this state. Consequently, the ACF reel 10 is carried in its longitudinal direction. The feed amount of the ACF reel 10 is controlled by the rotational speed (or rotational angle) of the gears 11 and 12.

According to the first embodiment of the invention, inserting the pins 15 into the perforation holes 5 and rotating the gears 11 and 12 causes the ACF reel 10 to be carried in its longitudinal direction. Moreover, inserting and fitting the pins 15 into the perforation holes 5 at the time of carrying the ACF reel 10 prevents the misalignment and the slipping of the ACF reel 10. This improves the carrying precision of the ACF reel 10, thereby contributing to the reduction in the size of the packages and modules.

Moreover, according to the first embodiment, the perforation holes 5 are formed only in the protruding regions 3a of the separator 3, and not in the ACF 1, which allows preventing the pins 15 from contacting the ACF 1 regardless of which side of the ACF reel 10 the pins 15 are inserted from.

Moreover, the perforation holes 5 are not formed in the ACF 1, which allows for using the ACF 1 without wastage. Specifically, holes in the ACF 1 may result in a poor connection between terminals as well as in an adhesive failure between the IC (semiconductor) chip and the PKG substrate. In order to resolve such problems, it is necessary, for instance, to partly die cut the ACR reel so that the sections including the holes are not bonded to the PKG substrate (for example, refer to FIG. 7B). However, according to the first embodiment, such die cutting is not necessary since there is no hole in the ACF 1, which allows for using the ACF 1 without wastage.

In the first embodiment, the ACF 1 corresponds to the ‘adhesive layer’ according to the aspect of the invention, and the separator 3 corresponds to the separator according to the aspect of the invention. Moreover, each of the perforation holes 5 corresponds to the ‘hole,’ and the ACF reel 10 corresponds to the ‘film-like adhesive’ according to the aspect of the invention.

### (2) Second Embodiment

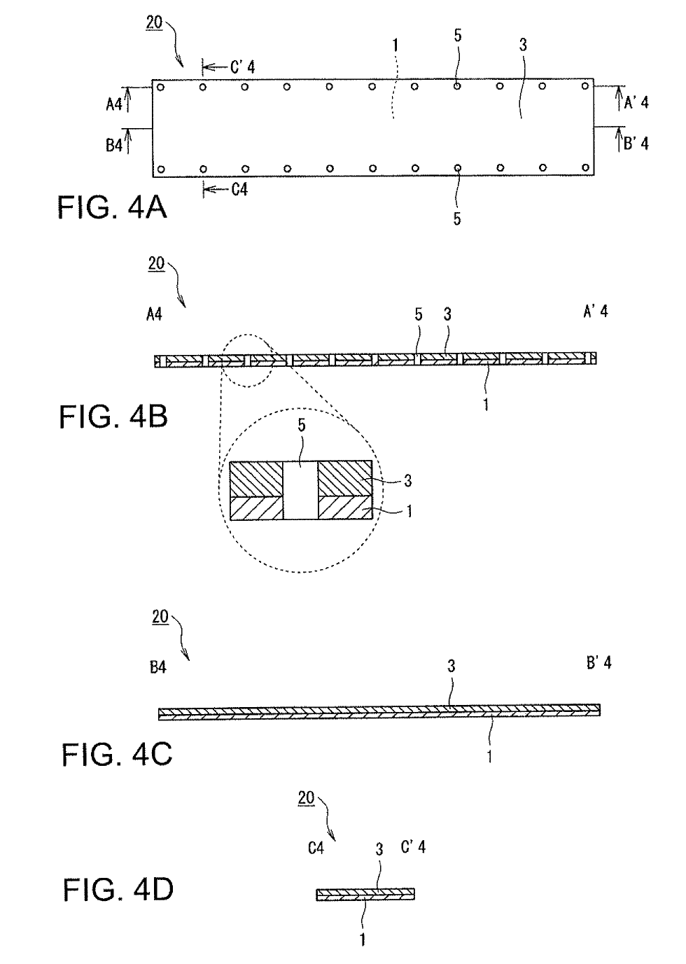

FIGS. 4A through 4D are drawings illustrating an example of a structure of an ACF reel 20 according to a second embodiment of the invention, where FIG. 4A is a plan view, FIG. 4B is a sectional view of FIG. 4A cut along A4-A′4, FIG. 4C is a sectional view of FIG. 4A cut along B4-B′4, and FIG. 4D is a sectional view of FIG. 4A cut along C4-C′4. The same signs and numerals as that of FIG. 1 are used in FIG. 4 for the parts with the same structure as indicated in FIG. 1, and the detailed description thereof is omitted.

As shown in FIGS. 4A through 4D, the ACF reel 20 is composed with the ACF 1 and the film-shaped separator 3 that overlaps with the ACF 1. Here, the width of the separator 3 is the same as that of the ACF 1. The ACF reel 20 is formed so that the separator 3 and the ACF 1 completely overlaps in plan view (in other words, without creating protruding regions). Moreover, the plurality of perforation holes 5 are formed on both sides of the ACF reel 20 along the longitudinal direction. These perforation holes 5 are through holes penetrating the separator 3 and the ACF 1 in the thickness direction, and are arranged in even space along the longitudinal direction of the ACF reel 20.

Similar to the first embodiment, such a structure also allows for carrying the ACF reel 20 in its longitudinal direction by inserting the pins 15 into the perforation holes 5 and rotating the gears. Moreover, inserting and fitting the pins 15 into the perforation holes 5 at the time of carrying the ACF reel 20 prevents the misalignment and the slipping of the ACF reel 20. This improves the carrying (feeding) precision of the ACF reel 20, thereby contributing to the reduction in the size of the packages and modules,

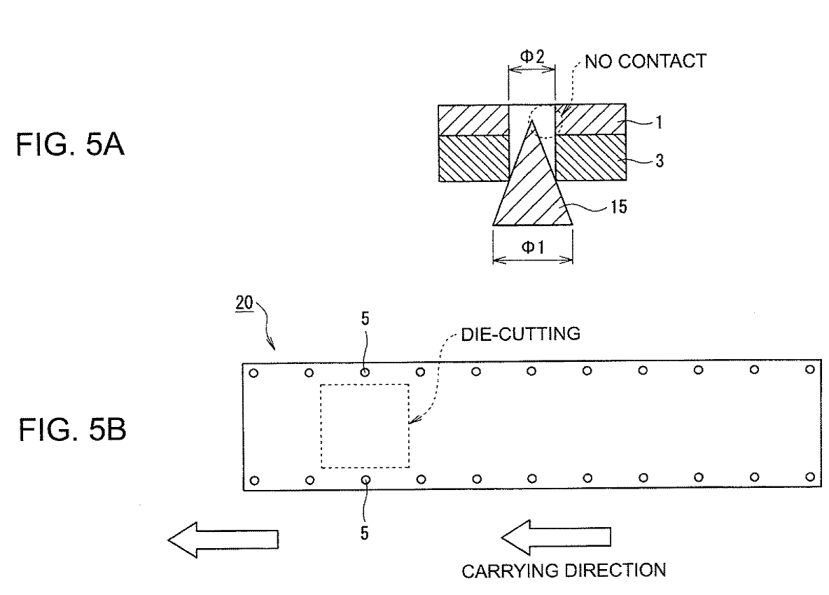

According to the second embodiment, it is desirable, as shown in FIG. 5A for instance, to set the maximum diameter ø1 of the pins 15 to be larger than a diameter ø2 of the perforation holes 5, and at the same time, to insert the pins 15 into the perforation holes 5 from the side of the separator 3 at the time of carrying the ACF 20. This prevents the pins 15 from contacting the ACF 1. Further, according to the second embodiment, it is desirable to partly die cut the ACR reel 20 so that the sections that includes the perforation holes 5 are not bonded to the PKG substrate at the time of adhering the ACF to the PKG substrate. This prevents the perforation holes 5 from being the cause of a poor connection between terminals, as well as of an adhesive failure between the IC chip and the PKG substrate.

In the second embodiment, the ACF reel 20 corresponds to the ‘film-like adhesive’ according to the aspect of the invention. The rest of the corresponding relationships of components are the same as that of the first embodiment. In the first and the second embodiments described above, the ACF reels 10 and 20 are described as examples of the ‘film-like adhesive’ according to the aspect of the invention. However, the film-like adhesive is not limited to the ACF, and may also include, for instance, NCF. In such case, the ACF 1 should be replaced with NCF in the first and the second embodiments. This NCF is formed with, for instance, thermosetting epoxy resin and does not include conductive particles. Such a structure including the perforation holes 5 allows for the similar effect as that of the first and the second embodiments.

In the first embodiment, the description is made for the case in which the perforation holes 5 penetrate only through the separator 3 in the thickness direction. In the second embodiment, the description is made for the case in which the perforation holes 5 penetrate through both the ACF 1 and the separator 3 in the thickness direction. However, the present invention is not limited to those cases, and may include, for instance, a case in which the perforation holes 5 penetrate only through the ACF 1 in the thickness direction.

Specifically, in an un-illustrated ACF reel having such a structure, the ACF is formed to be wider than the separator, and part of the ACF protrudes from both sides of the separator in the longitudinal direction. Moreover, perforation holes may be provided in protruding sections of the ACF outside the separator, so as to penetrate through the protruding sections in the thickness direction. Such a structure also allows for carrying the ACF reel in its longitudinal direction by inserting and fitting pins into the perforation holes formed in the ACF. Consequently, similar to the first and the second embodiment, the misalignment and the slipping of the ACF reel are prevented, thereby improving the carrying precision.

3. Comparing Present Invention to Known Techniques

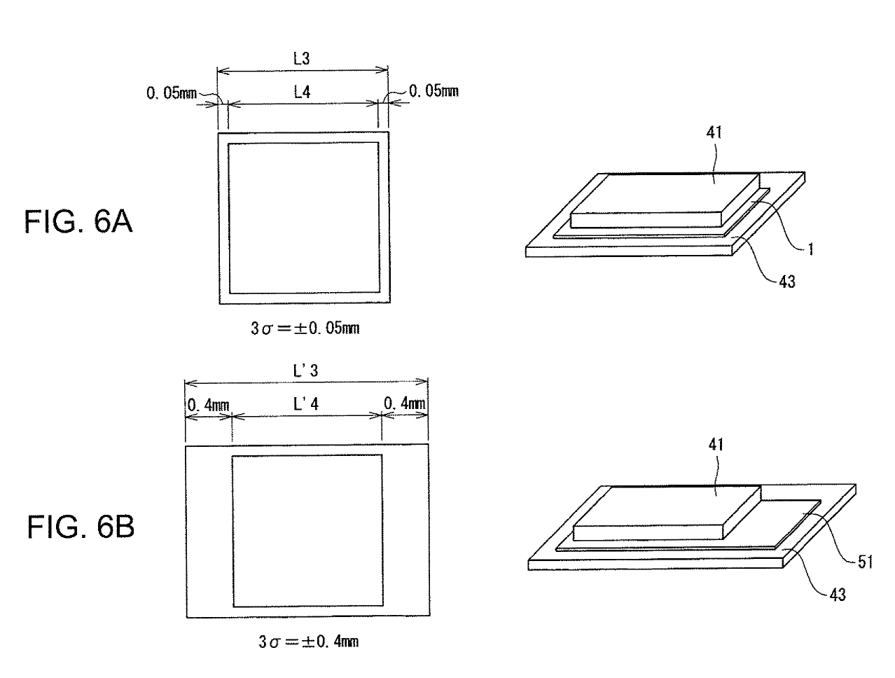

FIGS. 6A and 6B are drawings comparing the aspect of the invention and a known technique, where FIG. 6A relates to the aspect of the invention and FIG. 6B relates to the known technique.

According to the aspect of the invention, a so-called sprocket method, in which pins are inserted into perforation holes allows reducing 3σ to a range not exceeding ±0.05 mm and increasing the feeding precision of the ACR reel. Therefore, it is sufficient to set the feed amount of the ACF reel to (IC size+0.05*2) mm, which allows for reducing the ACF bonding area by that decreased size. Here, as shown in FIG. 6A, the relationship of L3 [mm] and L4 [mm] is represented as L3=L4+0.1, where L3 represents the package size and L4 represents the size of the IC chip 41 (IC size). If, for instance, the IC size L4 is 2.5 mm, then the package size L3 becomes 2.6 mm.

On the other hand, the range of 3σ in the known technique has been set to approximately ±0.4 mm. Therefore, it has been necessary to set the feed amount of the ACF reel to (IC size+0.4*2) mm, which ensures increasing the ACF bonding area by that increased size. As shown in FIG. 6B, the relationship of L′3 [mm] and L′4 [mm] is represented as L′3=L′4+0.8, where L′3 [mm] is the package size and L′4 [mm] is the IC size. If, for instance, the IC size L′4 is 2.5 mm, then the package size L′3 becomes 3.3 mm.

As described, the aspects of the invention allows for reducing the package size by 0.7 mm. This creates a package that has a size similar to the IC size.

Similar to the example of the package described above, size reduction of modules is possible for an un-illustrated electronic circuit that includes an IC chip and other devices such as resistors and inductances combined and mounted on the PKG substrate. For instance, in the case where the IC size is 2.5 mm and the other device size is 0.3 mm, the known technique produces a module size of 3.6 mm (=2.5+0.3+0.8), while the aspects of the invention produces a module size of 2.9 mm (=2.5+0.3+0.1). Consequently the module size is reduced by 0.7 mm.

What is claimed is:

1. A film-like adhesive, comprising:
a film that includes a separator and an adhesive layer provided on a first surface of the separator, the film including a hole going through at least one of the adhesive layer and the separator, the hole extending along a first direction, the first direction extending from the first surface of the separator to a second surface of the separator being opposite to the first surface of the separator.

2. The film-like adhesive according to claim 1, wherein:
the separator includes a protruding area protruding from the adhesive layer in plan view; and
the hole is provided only in the protruding area.

3. The film-like adhesive according to claim 2, wherein:
the protruding area is provided at each of both sides of the adhesive layer, along a longitudinal direction of the film; and
the hole is provided in the protruding area at each of the both sides.

4. The film-like adhesive according to claim 1, wherein the film includes a plurality of the holes, the plurality of the hole being equally spaced along a longitudinal direction of the film.

5. The film-like adhesive according to claim 1, wherein:
the separator includes a first section and a second section different from the first section;
the adhesive layer is provided only on the first section of the separator; and
the hole is provided only in the second section of the separator.

6. The film-like adhesive according to claim 5, wherein:
the film includes a plurality of the holes including a first hole and a second hole;
the second section of the separator includes a third section and a fourth section different from the third section;
the first section is positioned between the third section and the fourth section;
the first hole is provided in the third section; and
the second hole is provided in the fourth section,

7. A method for carrying a film-like adhesive, comprising:
inserting a pin into a hole of the film-like adhesive; and
carrying the pin in a longitudinal direction of a film,
wherein:
the film includes a separator and an adhesive layer provided on a first surface of the separator, the film including a hole going through at least one of the adhesive layer and the separator, the hole extending along a first direction, the first direction extending from the first surface of the separator to a second surface of the separator being opposite to the first surface of the separator.
